(19) United States
(12) Patent Application Publication
(10) Pub. No.: US 2009/0126783 A1
(43) Pub. Date: May 21, 2009

(54) USE OF VERTICAL ALIGNED CARBON NANOTUBE AS A SUPER DARK ABSORBER FOR PV, TPV, RADAR AND INFRARED ABSORBER APPLICATION

(75) Inventors: Shawn-Yu Lin, Niskayuna, NY (US); James A. Bur, Rensselaer, NY (US); Zu-Po Yang, Wynantskill, NY (US); Lijie Ci, Troy, NY (US); Pulickel M. Ajayan, Clifton Park, NY (US)

Correspondence Address: FOLEY AND LARDNER LLP;SUITE 500, 3000 K STREET NW, WASHINGTON, DC, 20007, US

(73) Assignee: Rensselaer Polytechnic Institute

(21) Appl. No.: 12/269,398

(22) Filed: Nov. 12, 2008

Related U.S. Application Data
(60) Provisional application No. 60/988,234, filed on Nov. 15, 2007.

(51) Int. Cl. G02B 5/22; H01L 31/00; B05D 5/06

(52) U.S. Cl. 136/252; 359/885; 427/74; 977/834; 977/752

(57) ABSTRACT

An optical absorber includes vertically aligned carbon nanotubes with an ultra-low reflectance less than 0.16% and an absorption efficiency greater than 99.84%. The index of refraction and the absorption constant are controlled by independently varying the nanotube diameter and nanotube spacing. The nanotubes are mostly double-walled. The density of the nanotube arrays is very low, around 0.015 g/cm³.

### CROSS REFERENCE TO RELATED PATENT APPLICATIONS

The present application claims benefit of U.S. Provisional Application No. 60/988,234, filed Nov. 15, 2007, which is hereby incorporated by reference in its entirety.

### BACKGROUND OF THE INVENTION

The present invention relates generally to carbon nanotube arrays and more specifically to carbon nanotube arrays used as super dark absorbers.

An article by Kodama et al. entitled “Ultra-black nickel-phosphorous alloy optical absorber”, IEEE Transactions on Instrumentation and Measurement, Vol. 39, No. 1 (1990) 230-232, which is incorporated herein by reference in its entirety, describes a nickel-phosphorous alloy with an integrated total reflectance of 0.16%-0.18% in the wavelength range of 488 nm to 1550 nm.

An article by Lehman et al. entitled “Carbon multi-walled nanotubes grown by HWCVD on a pyroelectric detector”, Infrared Physics & Technology, Vol. 47 (2006) 246-250, which is incorporated herein by reference in its entirety, describes carbon multi-walled nanotubes (MWNTs) grown on lithium niobate (LiNbNO₃) pyroelectric detectors by hot-wire chemical vapor deposition (HWCVD). The authors reported that the absolute spectral responsivity of their MWNT-coated detectors was relatively constant over a wavelength range from 600 nm to 1800 nm. However, the absorption efficiency of their MWNT-coated detectors was approximately 85%, which is inferior to the 99% absorption efficiency of gold-black coatings.

An article by Theocharous et al. entitled “Evaluation of pyroelectric detector with a carbon multiwalled nanotube black coating in the infrared”, Applied Optics, Vol. 45, No. 6 (2006) 1093-1097, which is incorporated herein by reference in its entirety, describes the spectral responsivity of the same MWNT-coated detectors of Lehman et al. extended to infrared wavelengths. The authors reported that the relative spectral responsivity of these detectors was relatively constant in the 1.6-14 μm wavelength range. However, the authors stated that it might be impossible to achieve an absorption efficiency greater than 90% for their MWNT-coated detectors.

### SUMMARY OF THE INVENTION

An embodiment of the present invention provides an optical absorber having at least one of an integrated total reflectance less than about 0.16% or an absorption efficiency greater than about 99.84%, for example an integrated total reflectance of about 0.10% and an absorption efficiency of about 99.90% as measured for incident light at normal incidence with a wavelength of 633 nm. The optical absorber includes an array of aligned tubular nanostructures having an index of refraction less than about 1.10, an absorption constant greater than about 0.01 μm⁻¹, and a major surface having a roughness factor less than about 0.01.

### BRIEF DESCRIPTION OF THE DRAWINGS

FIGS. 1A-C are scanning electron microscope (SEM) images of an optical absorber according to embodiments of the invention.

FIG. 1D is a transmission electron microscope (TEM) image of an optical absorber according to an embodiment of the invention.

FIG. 1E is a photograph taken under flash light illumination of an optical absorber according to an embodiment of the invention.

FIG. 2A is a schematic side view of an experimental setup used to measure the diffuse reflectance of an optical absorber.

FIG. 2B is a plot of measured diffuse reflectance versus detector angle for a wavelength of incident light having a wavelength of 633 nm. The incident angle was 0 degrees and the collecting solid angle was 8.2×10⁻⁴ Steradian for all samples except the Au mirror sample, for which the incident angle was −10 degrees.

FIG. 3A is a schematic top cross-sectional view of an experimental setup used to measure the integrated total reflectance of an optical absorber.

FIG. 3B is a plot of measured integrated total reflectance versus incident angle for a wavelength of incident light having a wavelength of 633 nm.

FIG. 4A is a plot of measured reflectance versus certified/calculated reflectance of incident light having a wavelength of 633 nm. The dashed line represents an ideal testing where the measured and certified/calculated values are exactly equal to one another.

FIG. 4B is a plot of total reflectance versus wavelength of incident light.

FIG. 5 is plot of calculated index-of-refraction and absorption constant versus inter-tube spacing. The inset of FIG. 5A shows a schematic side view of an optical absorber according to an embodiment of the invention, with light polarization directions S and P.

FIG. 6 is a schematic side view of a solar thermophotovoltaic (TPV) device according to an embodiment of the invention.

### DETAILED DESCRIPTION OF THE PREFERRED EMBODIMENTS

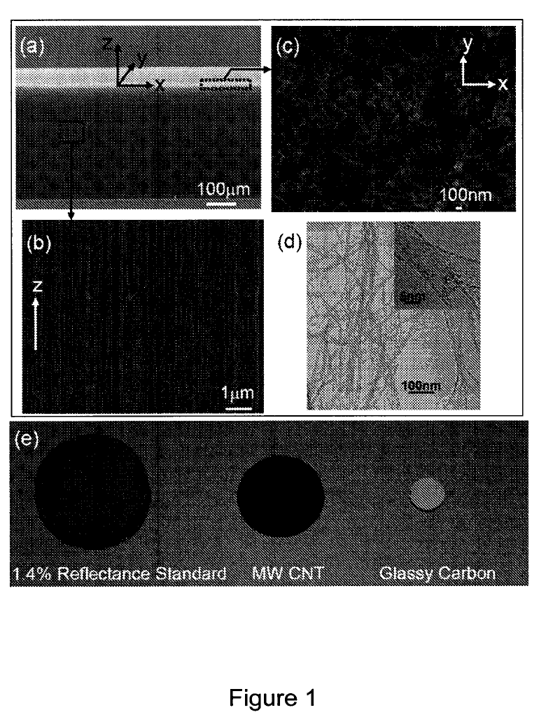

FIG. 1 shows an optical absorber according to an embodiment of the present invention. The absorber comprises an array of aligned tubular nanostructures that are substantially aligned in a direction substantially perpendicular to a major surface of the absorber. For example, in FIG. 1A, the exposed top surface defined by the X-Y plane is a major surface of the absorber. Tubular nanostructures include but are not limited to nanotubes, nanohorns, and nanowires. The tubular nanostructures preferably have a very high aspect ratio, preferably greater than 10,000. While the absorber of FIG. 1 comprises mostly carbon MWNTs, other types of nanotubes, such as carbon SWNTs and inorganic nanotubes, may also be used.

FIG. 1B shows a portion of a side thickness of the optical absorber of FIG. 1A. The carbon nanotubes are substantially aligned in the Z direction despite having some crookedness and bendedness. The term “substantially aligned” includes perfect alignment as well as alignment with slight to moderate overlap or cross-over between adjacent nanostructures. The Z direction is substantially perpendicular to at least one of the top major surface or the bottom major surface. The average spacing between adjacent nanotubes is about 10 nm to 60 nm, preferably greater than about 30 nm, for example 40 nm to 60 nm. The density of the array is preferably less than about 0.03 g/cm³, for example between about 0.02 g/cm³ to about 0.01 g/cm³, such as around 0.015 g/cm³. The volume filling fraction of the array is preferably less than about 10%, such as about 1% to about 9%. Without wishing to be bound to any particular theory, the present inventors believe that the highly porous structure of the array helps to facilitate the high absorption and low reflectance and transmittance of incident light.

FIG. 1C is a top-view SEM image of the 1 μm-thick, disordered layer highlighted in FIG. 1A. This top surface exhibits a randomly oriented and loosely connected network of carbon nanotubes with no discernable surface normal at this length scale, which is on the order of the wavelength of visible light. The surface corrugation is on the order of about 100 nm to about 1,000 nm, and the minimum feature size is the nanotube diameter itself. FIG. 1D shows that the average diameter of the nanotubes is about 8 nm to 11 nm. The nanotubes are preferably few-walled, for example having an average of 2 to 6 walls, such as 2 walls. Without wising to be bound to any particular theory, the present inventors believe that the randomly oriented and discontinuous surface at these length scales helps to facilitate the absorber's near angular-independent reflectance and high absorption of incident light. The nanotubes are understood to be “substantially aligned” and “substantially perpendicular” to the top major surface despite the presence of the 1 μm-thick disordered surface layer shown in FIG. 1C, due to the alignment of the nanotubes below the surface layer.

FIG. 1E illustrates qualitatively the low reflectance of the optical absorber compared with other carbon-based absorbers. The left-most sample is a standard NIST sample (U.S. National Institute of Standards and Technology, 1.4% reflectance at λ=450 nm to 700 nm). The right-most sample is a glassy carbon sample, which appears less dark than the 1.4% NIST sample. The middle sample is a sample of the absorber of the present invention (hereinafter “vertically-aligned carbon nanotube (VA-CNT)” sample) with the upper surface exposed. Due to the flash of the camera, all samples appear brighter in the picture than under actual conditions. Nevertheless, the VA-CNT sample appears darker than the other samples.

The optical absorber of FIG. 1 was prepared by water-assisted chemical vapor deposition (CVD). Prior to CNT growth, an electron-beam evaporator was used to deposit a 10 nm adhesion layer of aluminum and a 1 nm to 5 nm discontinuous catalyst layer of iron on the surface of a silicon wafer. The substrate was placed in the CVD growth chamber. Ethylene was used as a carbon source, and a 15% H₂ mixture of hydrogen and argon was used as a buffer gas. While the CVD chamber was heated to the CNT growth temperature (about 750° C. to about 800° C.), a stream of buffer gas was flowed through the CVD chamber at a flow rate of about 300 standard cubic centimeters per minute (sccm). Once the CVD chamber stabilized at the CNT growth temperature, the flow rate was increased to about 1300 sccm and a second stream of buffer gas was bubbled through water (which was kept at room temperature) prior to being provided into the CVD chamber at a flow rate of about 80 sccm. At the same time, ethylene gas was also flowed into the CVD chamber at a flow rate of about 100 sccm. Depending on the desired CNT thickness, the growth process was performed for 5 seconds up to 30 minutes, resulting in CNT film thicknesses of about 10 μm to about 800 μm. Larger thicknesses, for example thicknesses up to several millimeters, can be achieved for longer growth times. The CVD chamber was cooled to room temperature while under a buffer atmosphere. Other CNT deposition methods may also be used.

The density of the of the resultant CNT arrays was very low, such as about 0.01 g/cm³ to about 0.02 g/cm³. High resolution TEM (JEOL 2001) was performed to characterize the quality of the nanotube array and to analyze the diameter distribution. Under these growth conditions, the nanotubes were mostly multi-walled. For iron layers with thicknesses of about 1.5 nm, the nanotubes were mostly double-walled. Metal catalysts other than iron, for example nickel, can also be used. The average diameter of the nanotubes and the average spacing between adjacent nanotubes can be independently controlled, for example by varying the thickness of the iron and aluminum layers, the flow rates of the source and buffer gas, the composition of the buffer gas, and the humidity of the buffer gas. Although silicon wafers were used as the substrate, any substrate that remains stable up to the CNT growth temperature can be used, for example LiNbO₃, quartz, and mica can be used. The formed CNT films can then be removed from the substrate to result in free-standing films. The free-standing films can then be applied onto any kind of substrate, including those substrates that are otherwise incompatible with CVD growth. For instance, the free-standing films can be applied onto a pyroelectric substrate, such as lithium tantalite, for use as a pyroelectric detector. For large area applications, the CNT film can be grown on a large scale and then applied onto the outer surface of an object. For example, CNT films can be formed into tiles and assembled side-by-side onto a surface, like a mosaic, for use in photovoltaic, thermophotovoltaic, radar and infrared absorption applications. Optionally, multiple layers of tiles can be stacked on top of each other and assembled onto a surface.

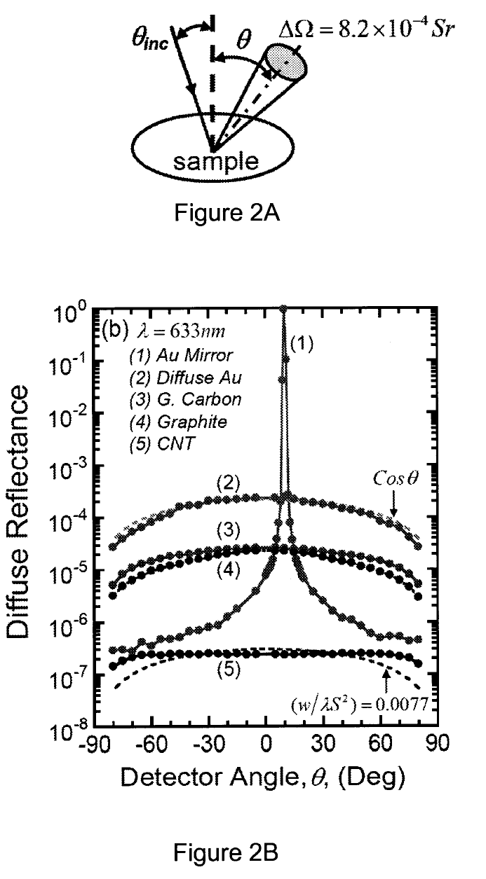

FIG. 2A shows the experimental setup used to measure the diffuse reflectance of the optical absorber. Laser light is incident at an angle θ_{inc} and is detected at a detection angle θ. All angles are measured relative to the surface normal of the top major surface. The wavelength of incident light was 633 nm. The laser was polarized perpendicular to the plane defined by the incident light and the sample's surface normal. The incident power was fixed at 10 nW and was stable to within 2%. A calibrated silicon photodetector was used for reflection power detection and had a detecting area of (10×10) mm² and an accuracy of better than 3 The corresponding collecting solid angle was ΔΩ=8.2×10⁻⁴ Steradian. The detector's linearity was verified to be linear over a large dynamic range from 1 nW to 30 mW. The noise level of the detector was 0.05 nW at room temperature. All measurements were taken at θ_{inc}=0 degrees, except for the Au-mirror for which (θ_{inc}=−10 degrees.

FIG. 2B plots the measured diffuse reflectance for (1) an Au mirror, (2) diffuse Au, (3) glassy carbon, (4) a piece of graphite, and (5) a VA-CNT sample. For the Au mirror, a strong peak is observed at θ=+10 degrees with a reflectance of 94.5%. The reflectance decreases quickly to below R≈10⁻⁶ for |θ_{inc}|≧40 degrees. This is a characteristic feature of specular reflection from an optically smooth reflecting surface. Diffuse Au is also a good reflector, yet it scatters light in random directions. The reflectance exhibits a Cosine functional dependence (represented by the dashed line (2) in FIG. 2B) on θ and achieves a maximum value of R≈2×10⁻⁴ at |θ|≦5 degrees. This dependence is known as the Lambertian distribution and is characteristic of randomly scattered light.

FIG. 2B shows that glassy carbon and graphite also exhibit a Lambertian-like reflectance, but have a maximum reflectance of R≈2×10⁻⁴ at |θ|≦5 degrees. This reflectance is ten times lower than that of diffused Au and is conventionally viewed as a black object. Although not wishing to be bound to any particular theory, the present inventors believe that the much lower reflectance of glassy carbon and graphite is due to a combination of the random scattering of light, a smaller refractive index of the carbon-based material, and the material's absorption. Assuming a Lambertian distribution over 2π angles and using a ΔΩ=8.2×10⁻⁴ Steradian, a total reflectance of (10±1) % is obtained for the glassy carbon.

FIG. 2B also shows that the VA-CNT sample exhibits a diffuse reflectance. However, the VA-CNT sample does not have an observable dependence on θ for |θ|≦70 degrees. More strikingly, its reflectance is measured to be R≦2×10⁻⁷ for |θ|≦5, which is about two orders of magnitude lower than that of either graphite or glassy carbon. This is a remarkable observation because all of the samples are made up of the same element: carbon. The data in FIG. 2B also quantitatively confirms the brightness contrast between the VA-CNT and glassy carbon that is seen in the photos in FIG. 1(e).

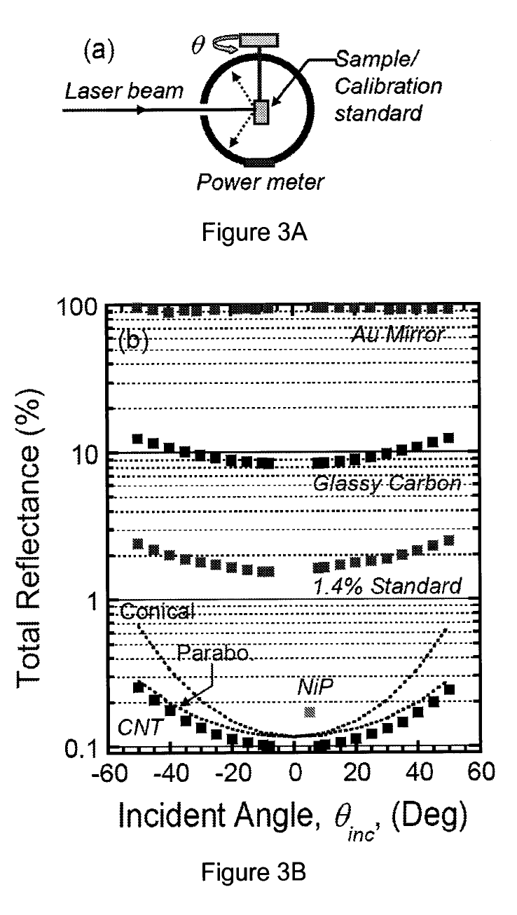

FIG. 3A shows the experimental setup used to measure the integrated total reflectance of an optical absorber. A commercially available integrating sphere was used. Several visible lasers were used for testing, including λ=633 nm from a He—Ne laser, and λ=514 nm, 488 nm, and 458 nm from an Ar-laser. A laser beam is incident onto the sample, which is mounted at the center of the sphere. It is noted that when the sample is mounted at the vortex of the integrating sphere, the measured reflectance tends to be lower than its true value. This is because the sample blocks part of the interior of the reflective integrating sphere and, therefore, reduces the final reflective power. The reflected light from the sample is scattered by the integrating sphere and is subsequently collected by a silicon photodetector. The incident angle may be varied by rotating the sample mount. Proper black shielding and optical alignment are implemented to prevent leakage of stray light into the integrating sphere. A normalization procedure is used to obtain an accurate reflectance. First, the reflecting power from a 99.0% standard is measured and recorded as a reference signal. Second, the reflecting power is measured and normalized to the reference signal. Third, the accuracy of the measurement is further checked using an Au mirror and a NIST calibration standard. The measured Au reflectance of the mirror is R=94.5%. The computed Au reflectance is R=94.1% at λ≈633 nm, according to an article by Garcia-Vidal et al., “Effective Medium Theory of the Optical Properties of Aligned Carbon Nanotubes”, Phys. Rev. Lett. 78, 4289 (1997), which is incorporated herein by reference in its entirety. The measured and computed values agree well for the Au mirror. The NIST sample has a certified reflectance of Rₜₒₜₐₗ=1.4% at λ=450 nm to 700 nm, which is the lowest reflectance standard currently available for testing. A value of Rₜₒₜₐₗ=1.6% was measured by the experimental setup. The measured and certified values agree well for the NIST sample.

FIG. 3B plots the measured integrated total reflectance versus incident angle, θ_{inc}, for an Au mirror, glassy carbon, 1.4% NIST standard, and a VA-CNT sample. For comparison, the 0.16% to 0.18% value of the spectral reflectance reported by Kodama et al. for their nickel-phosphorous alloy is also plotted in FIG. 3B. Total reflectance of the Au mirror remains at Rₜₒₜₐₗ=94% for all angles of incidence. Total reflectance of the glassy carbon is measured to be Rₜₒₜₐₗ=8.5% at normal incidence (θ_{inc}=0 degrees), which agrees with that estimated from the angular dependent data. The total reflectance has a slight θ_{inc} dependence and increases to 12.5% at θ_{inc}=50 degrees. In a general sense, this θ_{inc} dependence may be understood from a geometrical consideration. An increase in θ_{inc} corresponds to a reduction in the effective root mean square of the surface roughness by an amount, Cos(θ_{inc}), which increases the total reflectance. Total reflectance of the 1.4% NIST sample also increases slightly from 1.4 to 2.8% as θ_{inc} is increased from 0 degrees to 50 degrees. For the VA-CNT sample, the total reflectance was measured to be Rₜₒₜₐₗ≦0.10% at |θ_{inc}|≦10 degrees, and increases to Rₜₒₜₐₗ=0.28% at θ_{inc}=50 degrees. This observed reflectance of 0.10% is 60-80% lower than the previously reported reflectance value of Rₜₒₜₐₗ=0.16% to 0.18% by Kodama et al. for their nickel phosphorous alloy. Additionally, the transmittance was found to be below the detection level of the equipment, thus T is about 0.00%. Accordingly, the absorption efficiency is greater than about 99.84%, for example greater than about 99.86% for 450 nm≦λ≦700 nm and |θ_{inc}|≦10 degrees, such as about 99.90% for λ=633 at normal incidence.

The role of surface roughness is considered herein. In a simple description, a rough surface may be characterized by the root mean square of the diffuser height σᵣₘₛ and the correlation length of the diffuser roughness, w. A strong surface corrugation is represented by a large σᵣₘₛ and a large phase-delay, S=4π(σᵣₘₛ/λ)Cosθ_{inc}. As the surface gets rougher, the correlation length, w, becomes shorter. Assuming a simple conical scatterer, the diffuse reflectance data is fit to a model calculation with a single roughness factor, (w/λS²). The least-square fit yields (w/λS²)=0.0077<<1, which suggests that the VA-CNT sample is a strong diffuser. However, the fitted curve (represented by dashed line (5) in FIG. 2B) predicts a much stronger angle dependence than observed experimentally. The predicted total reflectance, Rₜₒₜₐₗ=0.12%, is also slightly higher than observed experimentally. The data in FIG. 2B was fitted to a paraboloidal scatterer, which obtained a similar result (not shown) as the conical scatterer. In addition, the data in FIG. 3B was fitted for both conical and paraboidal scatterers and are represented as dashed lines in FIG. 3B. Again, the model describes the overall trend but predicts a much stronger θ dependence than observed experimentally. These modeling results suggest that the CNT surface morphology is not easily described by simple scattering models. Contrary to conventional rough surfaces, the VA-CNT array does not have a continuous surface. The surface contains a loosely connected and disordered network of nanotubes without a well-defined surface-normal at length scales on the order of optical wavelengths.

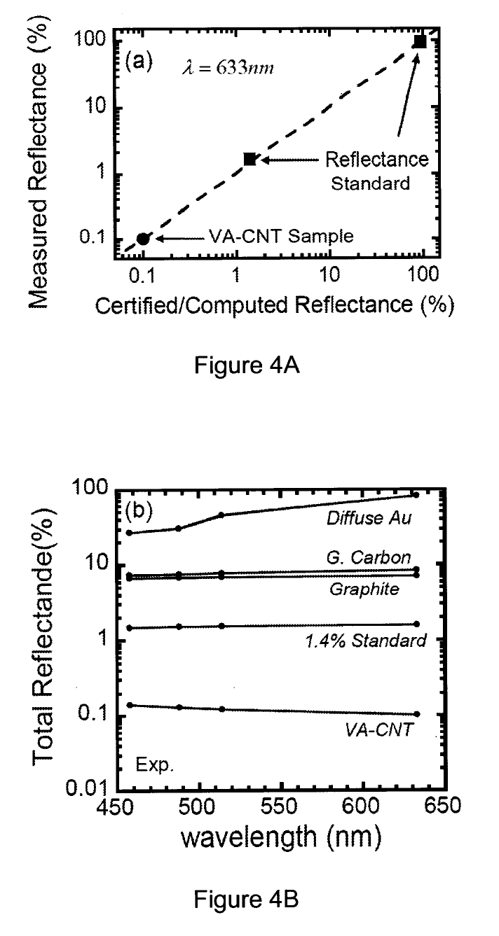

FIG. 4A plots the measured reflectance versus the certified or computed reflectance for the VA-CNT sample, the Au mirror, and the 1.4% NIST samples. The dashed line represents an ideal testing where measured and certified/calculated values are exactly equal each other. The circular dot is the measured value for the VA-CNT sample. By a careful calibration at both the high (Rₜₒₜₐₗ=94%) and low (Rₜₒₜₐₗ=1.4%) reflectance regimes, the precision of the measurement is verified. FIG. 4A shows that the VA-CNT sample may serve as a new standard of low reflectance in the 0.1% to 1.0% reflectance range.

FIG. 4B plots the total reflectance versus wavelength for a range of wavelengths from 457 nm to 633 nm. The diffuse Au-sample has a lower reflectance at shorter wavelengths due to a stronger visible absorption. The glassy carbon, graphite, and 1.4% NIST sample all exhibit a weak wavelength -dependence. The total reflectance for the VA-CNT sample also has a weak wavelength-dependence. It increases slightly from 0.10% to 0.13% as wavelength is decreased from 633 nm to 457 nm. Hence, the VA-CNT sample maintains an ultra low reflectance throughout the entire visible wavelength.

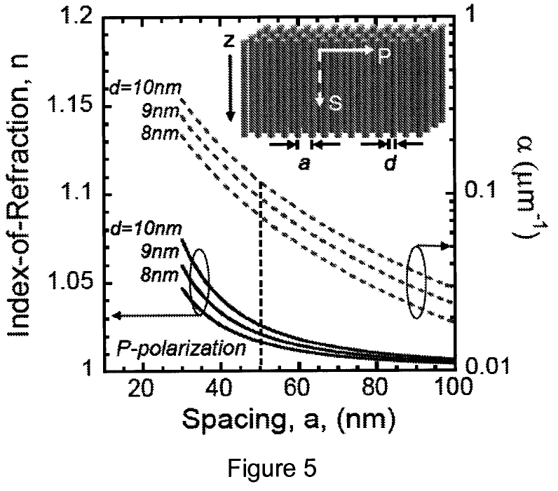

FIG. 5 plots the calculated index of refraction, n, and absorption constant, α, versus inter-nanotube spacing, α, for an optical absorber under P light polarization. The dielectric properties of an aligned array of tubular nanostructures can be described by an effective medium theory assuming that the array is in the dilute limit, as is described in the article by Garcia-Vidal et al., “Effective Medium Theory of the Optical Properties of Aligned Carbon Nanotubes,” Phys. Rev. Lett. Vol. 78, 4289-4292 (1997), which is incorporated herein by reference in its entirety. The inset of FIG. 5 shows a schematic of an aligned CNT array, with S and P light polarizations. The VA-CNT array has α=(50±10) nm, nanotube diameter d=8 nm to 10 nm, and a volume filling fractions ƒ≈2% to 3%. In FIG. 5, the computed effective index of refraction and absorption constant for P polarization are shown as lower and upper curves, respectively. In the calculation, the individual nanotube is assumed to have the dielectric function of graphite, which depends on light polarization. For α=50 nm and d=8 nm, the VA-CNT array has an effective index of refraction n^{p}_{effective}1.03. This index value is very small and could lead to a specular reflectance of 0.07%. An attempt to directly measure the index of refraction by elliposometry was not successful because the sample reflectance is diffused. Furthermore, the reflection signal from the CNT sample is too weak to yield reliable readings. From conservation of energy principles, the total incident energy must equal the energy that is transmitted, reflected, and absorbed. An ideal absorber has T=0, R=0, and A=100%. Hence, the optical absorber preferably has a high absorption constant. FIG. 5 shows that an optical absorber with α=50 nm and d=10 nm has an absorption constant α=0.12 μm⁻¹. The corresponding absorption length is 8.3 μm, which is much smaller than the film thickness of the VA-CNT sample in FIG. 1A. The absorption might also be enhanced at the surface due to light localizations and trapping. Surface scattering may also be present. The optical absorber of the present invention combines a low refractive index, a strong absorption, and a rough surface nanostructure. The multi-walled carbon nanotubes of the VA-CNT array contain a mixture of metallic and semiconducting CNTs, which are intrinsically absorptive and exhibit birefringement. However, single-walled carbon nanotubes as well as other types of tubular nanostructures can also be used to achieve low reflectance and high absorption.

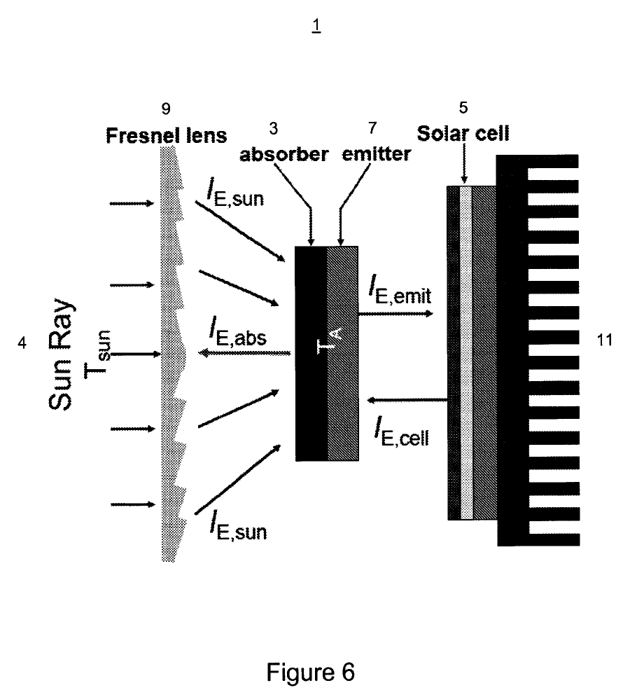

FIG. 6 illustrates a solar thermophotovoltaic (TPV) device 1 that contains an optical absorber 3. The absorber 3 is placed between the solar rays 4 (i.e., the radiation inlet of the device) and a solar cell 5. The absorber 3 is heated by absorbing solar radiation, and its emitted radiation is converted into electrical energy by the solar cell 5. Hence, the absorber 3 converts the high-energy, visible wavelength, solar radiation into lower-energy, longer wavelength, thermal radiation in the infrared. Thus, a solar (i.e., photovoltaic) cell 5 which has a peak sensitivity in the IR rather than in the visible range can be used. The device 1 also includes an emitter 7, which transfers the emitted radiation from the absorber 3 to the solar cell 5. The emitter 7 not only alters the blackbody radiation, but it also changes the balance of energy flow between the sun ray (I_{E,sun}), the absorber (I_{E, abs}), and the emitter (I_{E, emit}). This energy balancing and the degree of solar concentration (solar concentration factor) dictate the absorber's temperature (T_{A}). The emitter 7 can include, for example, a 3D metallic photonic crystal, which is described in the articles by S. Y. Lin et al., “Experimental observation of photonic-crystal emission near a photonic band-edge”, Appl. Phys. Lett., Vol. 83, 593 (2003) and S. Y. Lin et al., “Highly Efficient Light Emission at λ=1.5 μm from a 3D Tungsten Photonic Crystal”, Optics. Lett. 28, 1683 (2003), both of which are incorporated herein by reference in their entirety. The VA-CNT array is an ideal candidate for solar TPV conversion applications because of the high thermal stability of carbon nanotubes. The absorber can operate at high temperatures, for example at temperatures of at least 1,500 K. The device 1 may also contain an optional light concentration device 9, such as a Fresnel or other type of lens and an optional heat sink 11 attached to the solar cell 5.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

1-41. (canceled)

42. An optical absorber having at least one of an integrated total reflectance less than about 0.16% or an absorption efficiency greater than about 99.84%.

43. The optical absorber of claim 42, wherein the absorber comprises the integrated total reflectance less than about 0.16%.

44. The optical absorber of claim 42, wherein the absorber comprises the absorption efficiency greater than about 99.84%.

45. The optical absorber of claim 42, wherein the absorber comprises the integrated total reflectance less than about 0.16% and the absorption efficiency greater than about 99.84%

46. The optical absorber of claim 42, wherein:
the integrated total reflectance is less than about 0.14%;
the integrated total reflectance is measured for a wavelength of incident light of about 450 nm to about 700 nm; and
the incident light is disposed at an incident angle of −10 degrees to 10 degrees relative to the surface normal of a major surface of the absorber.

47. The optical absorber of claim 46, wherein the integrated total reflectance is equal to about 0.10%, the wavelength of the incident light is equal to about 633 nm and the incident angle is equal to about 0 degrees.

48. The optical absorber of claim 47, further having a diffuse reflectance less than or equal to about 2×10⁻⁷.

49. The optical absorber of claim 48, wherein:
the diffuse reflectance is measured at a detection angle of −5 degrees to 5 degrees relative to the surface normal of the major surface of the absorber; and
the detection angle comprises a collecting solid angle of about 8.2×10⁻⁴ Steradian.

50. The optical absorber of claim 42, further comprising a transmittance equal to about 0%.

51. The optical absorber of claim 42, wherein:
the absorber comprises an array of aligned, tubular nanostructures; and
the nanostructures are substantially aligned in a direction substantially perpendicular to the major surface.

52. The optical absorber of claim 51, wherein:
the nanostructures comprise multi-walled carbon nanotubes;
the array comprises a density of about 0.01 g/cm³ to about 0.02 g/cm³;
the major surface comprises a rough surface layer;
the nanotubes comprise an average diameter of about 8 nm to about 11 nm; and
the array comprises an average spacing between adjacent nanotubes of about 10 nm to about 60 nm.

53. The optical absorber of claim 52, wherein the average spacing is greater than about 30 nm.

54. The optical absorber of claim 42, wherein:
the absorption efficiency is greater than about 99.86%;
the absorption efficiency is measured for a wavelength of incident light of about 450 nm to about 700 nm; and
the incident light is disposed at an incident angle of −10 degrees to 10 degrees relative to the surface normal of a major surface of the absorber.

55. The optical absorber of claim 54, wherein the absorption efficiency is equal to about 99.90%.

56. An optical absorber comprising:
an array of tubular nanostructures;
an index of refraction less than about 1.10;
an absorption constant greater than about 0.01 μm⁻¹; and
a major surface of the absorber having a roughness factor less than about 0.01;
wherein:
the nanostructures are substantially aligned in a direction substantially perpendicular to the major surface; and
the index of refraction and the absorption constant correspond to a light polarization in the direction substantially perpendicular to the major surface.

57. The optical absorber of claim 56, wherein:
the index of refraction is about 1.02 to about 1.06; and
the absorption constant is about 0.015 μm⁻¹ to about 0.13 μm⁻¹.

58. The optical absorber of claim 57, wherein:
the index of refraction is about 1.03;
the absorption constant is about 0.12 μm⁻¹; and
the roughness factor is equal to about 0.0077.

59. The optical absorber of claim 56, wherein:
the nanostructures comprise carbon nanotubes; and
the array comprises a density of about 0.01 g/cm³ to about 0.02 g/cm³.

60. The optical absorber of claim 56, wherein the density is equal to about 0.015 g/cm³.

61. The optical absorber of claim 56, wherein:
the nanotubes comprise multi-walled nanotubes having an average of 2 to 6 walls and an average diameter of about 8 nm to about 11 nm;
the array comprises an average spacing between adjacent nanotubes of about 10 nm to about 60 nm;
the major surface comprises a disordered layer of carbon nanotubes.

62. The optical absorber of claim 56, further comprising at least one of an integrated total reflectance less than about 0.16% or an absorption efficiency greater than about 99.84%.

63. A photovoltaic or thermophotovoltaic device comprising the absorber of claim 56.

64. A method of making an optical absorber, comprising:
providing a substrate comprising a substrate surface and a metal catalyst layer formed on the substrate surface;
providing a carbon nanotube source gas and a buffer gas onto the substrate; and
growing an array of carbon nanotubes on the catalyst layer;
wherein:
the buffer gas is at least partially humidified;
the nanotubes are substantially aligned in a direction substantially perpendicular to the substrate surface; and
the nanotubes comprise multi-walled nanotubes.

65. The method of claim 64, wherein:
the nanotubes comprise double-walled nanotubes;
the array comprises a density of about 0.01 g/cm³ to about 0.02 g/cm³;
the metal catalyst layer comprises an iron catalyst layer having a thickness of about 1 nm to about 5 nm;
the substrate surface comprises an aluminum layer located over an underlying substrate;
the source gas comprises ethylene;
the buffer gas comprises a mixture of argon and hydrogen;
the step of growing is performed at a temperature of about 750° C. to about 800° C.; and
the buffer gas is at least partially humidified with water.

66. The method of claim 65, wherein:
the carrier gas is provided onto the substrate at a flow rate of about 100 sccm;
the buffer gas comprises a first stream and a second stream;
the first stream is bubbled through water prior to being provided onto the substrate at a flow rate of about 80 sccm; and
the second stream is provided onto the substrate at a flow rate of about 1300 sccm without being bubbled through water prior to being provided onto the substrate.

67. The method of claim 64, further comprising removing the array from the catalyst layer and attaching the array to another surface.
